(19) United States
(12) Patent Application Publication
(10) Pub. No.: US 2025/0031419 A1
(43) Pub. Date: Jan. 23, 2025

(54) Stacked Multi-Gate Device With Reduced Contact Resistance And Methods For Forming The Same

(71) Applicant: Taiwan Semiconductor Manufacturing Company, Ltd., Hsin-Chu (TW)

(72) Inventors: Kuan-Kan Hu, Hsinchu (TW); Po-Chin Chang, Taichung City (TW); Olivia Pei-Hua Lee, Hsinchu County (TW); Ku-Feng Yang, Hsinchu County (TW); Sung-Li Wang, Hsinchu County (TW); Szuya Liao, Hsinchu County (TW)

(21) Appl. No.: 18/353,732

(22) Filed: Jul. 17, 2023

(51) Int. Cl. H01L 29/06; H01L 21/8234; H01L 27/088; H01L 29/417; H01L 29/423; H01L 29/49; H01L 29/66; H01L 29/775; H01L 29/786

(52) U.S. Cl. CPC H01L 29/0673; H01L 21/823418; H01L 27/088; H01L 29/41733; H01L 29/42392; H01L 29/4975; H01L 29/66439; H01L 29/775; H01L 29/78696

(57) ABSTRACT

Method to form low-contact-resistance contacts to source/drain features are provided. A method of the present disclosure includes receiving a workpiece including an opening that exposes a surface of an n-type source/drain feature and a surface of a p-type source/drain feature, selectively depositing a first silicide layer on the surface of the p-type source/drain feature while the surface of the n-type source/drain feature is substantially free of the first silicide layer, depositing a metal layer on the first silicide layer and the surface of the n-type source/drain feature, and depositing a second silicide layer over the metal layer. The selectively depositing includes passivating the surface of the surface of the n-type source/drain features with a self-assembly layer, selectively depositing the first silicide layer on the surface of the p-type source/drain feature, and removing the self-assembly layer.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and multi-bridge-channel (MBC) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor. The channel region of an MBC transistor may be formed from nanowires, nanosheets, other nanostructures, and/or other suitable structures. The shapes of the channel region have also given an MBC transistor alternative names such as a nanosheet transistor or a nanowire transistor.

As the semiconductor industry further progresses in pursuit of higher device density, higher performance, and lower costs, challenges from both fabrication and design issues have led to stacked device structure configurations, such as complementary field effect transistors (C-FET). While existing C-FET structures are generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method for forming low-resistance source/drain contacts for a C-FET structure, according to one or more aspects of the present disclosure.

FIGS. 2-15 illustrate fragmentary cross-sectional views of a workpiece undergoing various fabrication processes in the method of FIG. 1, according to one or more aspects of the present disclosure.

FIG. 16 illustrates a mechanism for selectively depositing a first silicide layer on a p-type source/drain feature, according to one or more aspects of the present disclosure.

FIGS. 17-19 illustrate an alternative mechanism for selectively depositing a first silicide layer on a p-type source/drain feature, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

A stacked multi-gate device refers to a semiconductor device that includes a first multi-gate device and a second multi-gate device stacked over the first multi-gate device. When the first multi-gate device and the second multi-gate device are of different conductivity types, the stacked multi-gate device may be a complementary field effect transistor (C-FET). The multi-gate devices in a C-FET may be FinFETs or MBC transistors. The vertical stacking creates challenges for formation of source/drain features. In some instances, a contact feature may extend through a top source/drain feature to contact a bottom source/drain feature. This creates concerns in increase of contact resistance as the longer source/drain contact features and small contact areas may increase contact resistance. In some existing schemes, source/drain contacts interface n-type and p-type source/drain features by way of the same type of metal silicide features. It is desirable to further reduce contact resistance with the source/drain features.

The present disclosure provides process to selectively deposit a first silicide layer on p-type source/drain features to reduce contact resistance. An n-type source/drain feature may include silicon and an n-type dopant and a p-type source/drain feature may include silicon germanium and a p-type dopant. In one embodiment, metal precursors that are selective to silicon germanium surfaces are used to selectively deposit the first silicide layer on p-type source/drain features. In another embodiment, a self-assembled monolayer (SAM) blocking layer is selectively deposited on germanium-free surfaces before the first silicide layer is deposited on p-type source/drain features. After the selective deposition of the first silicide layer, a n-type dipole layer is globally deposited on the first silicide layer and n-type source/drain features. A second silicide layer is then deposited on the n-type dipole layer. The interface with the first silicide layer reduces contact resistance with the p-type source/drain features and the interface with the n-type dipole layer reduces contact resistance with the n-type source/drain features. In some instances, by using the processes of the present disclosure, the contact resistance to both p-type and n-type source/drain features may be reduced to below 1×10⁻⁹ ohm-cm₂.

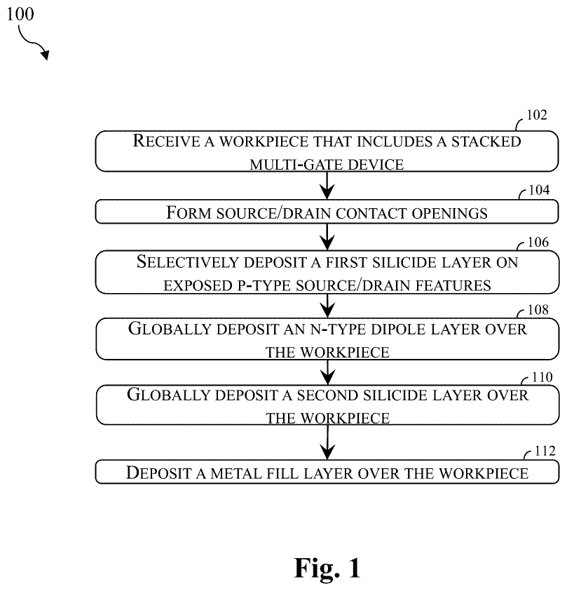

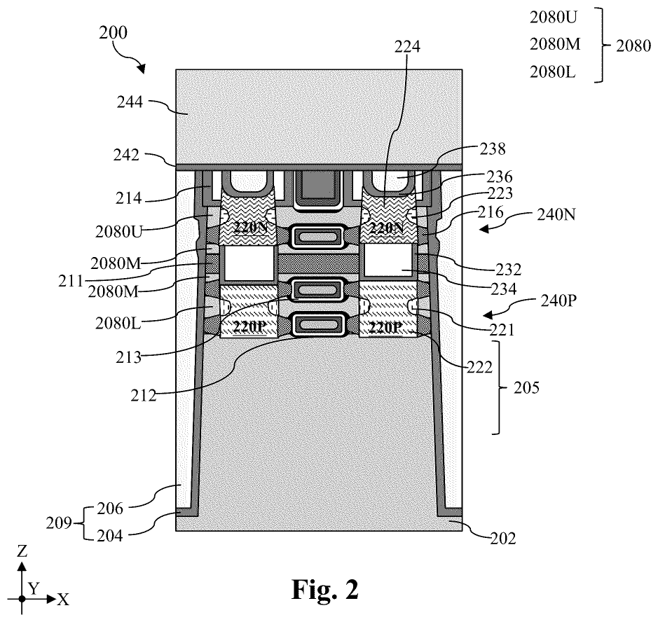

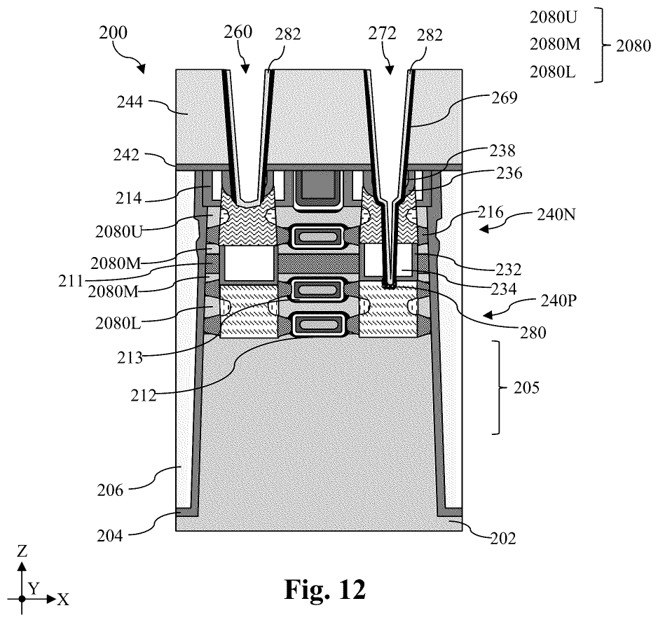

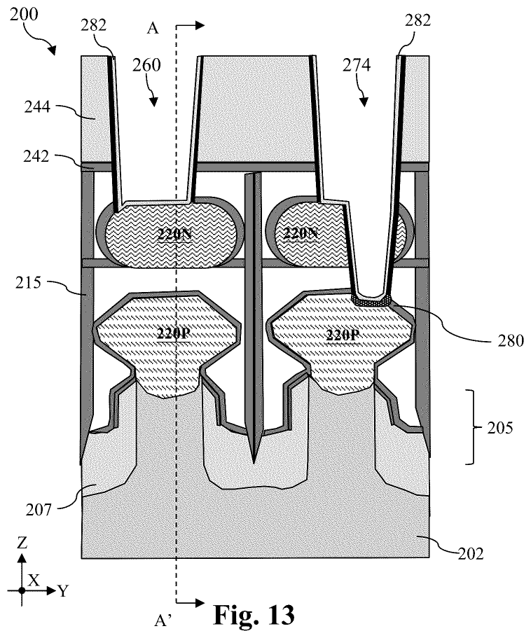

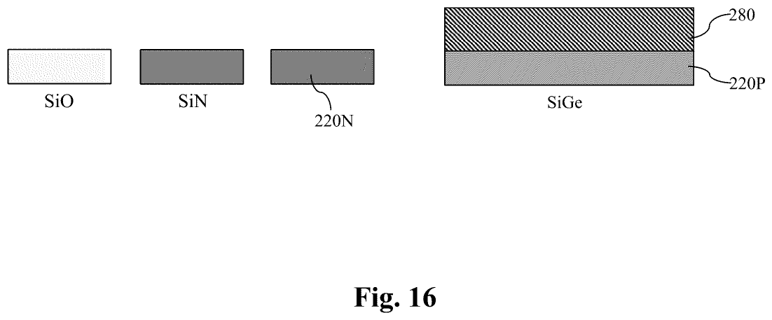

The various aspects of the present disclosure will now be described in more detail with reference to the figures. In that regard, FIG. 1 is a flowchart illustrating method 100 for forming low-resistance source/drain contacts in a stacked multi-gate structure. Method 100 is merely an example and is not intended to limit the present disclosure to what is explicitly illustrated in method 100. Additional steps may be provided before, during and after method 100, and some steps described can be replaced, eliminated, or moved around for additional embodiments of the method. Not all steps are described herein in detail for reasons of simplicity. Method 100 is described below in conjunction with FIGS. 2-15, which are fragmentary cross-sectional views of a workpiece 200 at various stages of fabrication according to embodiments of method 100. FIGS. 16-19 illustrates two example mechanisms to selectively deposit a silicide layer on p-type source/drain features. Because the workpiece 200 will be fabricated into a semiconductor structure 200 upon conclusion of the fabrication processes, the workpiece 200 may be referred to as the semiconductor structure 200 as the context requires. Additionally, throughout the present application, like reference numerals denote like features, unless otherwise excepted.

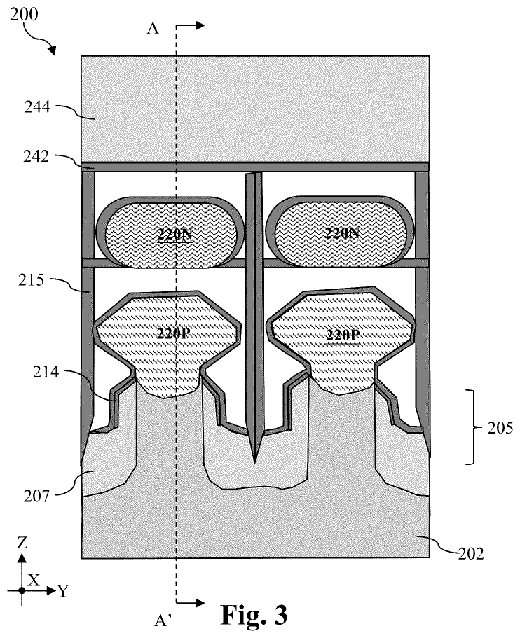

Referring to FIGS. 1, 2 and 3, method 100 includes a block 102 where a workpiece 200 is provided. As shown in FIGS. 2 and 3, the workpiece 200 includes a stacked multi-gate device structure formed on a substrate 202. In the depicted embodiment, the stacked multi-gate device structure is a C-FET structure. The substrate 202 may include an elementary (single element) semiconductor, such as silicon (Si), germanium (Ge), and/or other suitable materials; a compound semiconductor (i.e., alloy semiconductor), such as silicon carbide (SiC), gallium arsenic (GaAs), gallium phosphide (GaP), indium phosphide (InP), indium arsenide (InAs), indium antimonide (InSb), silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), gallium indium phosphide (GaInAsP), and/or other suitable materials. The substrate 202 may be a single-layer material having a uniform composition. Alternatively, the substrate may include multiple material layers having similar or different compositions suitable for IC device manufacturing. In one example, the substrate may be a silicon-on-insulator (SOI) substrate having a silicon layer formed on a buried silicon oxide (BOX) layer. In some embodiments, the substrate includes various doped regions, such as n-type wells or p-type wells. The doped regions may be doped with n-type dopants, such as phosphorus (P) or arsenic (As), and/or p-type dopants, such as boron (B) or BF₂, depending on design requirements. Doped regions may be formed by implantation of dopant atoms, in-situ doped epitaxial growth, and/or other suitable techniques. In the depicted embodiments, the substrate 202 includes silicon (Si).

Referring to FIGS. 2 and 3, the workpiece 200 includes active regions extending lengthwise along the X direction and gate structures (including upper gate structures 240N and lower gate structures 240P) extending lengthwise along the Y direction. FIG. 3 cuts along Y direction while FIG. 2 cuts along X direction along line A-A′ in FIG. 3. Referring to FIGS. 2 and 3, a portion of the substrate 202 is patterned into fin structures 205. The fin structures 205 rise continuously from the substrate 202 and are surrounded by an isolation feature 207. The isolation feature 207 may include silicon oxide. A plurality of channel members 2080 are disposed over a channel region of the fin structure 205. The active regions includes a plurality of channel members 2080, including a lower channel member 2080L, middle channel members 2080M, and an upper channel member 2080U. Like the fin structure 205, the plurality of channel members 2080 extend along X direction. The fin structure 205 and the channel members 2080 may be collectively referred to as an active region. Along the Z direction, the plurality of the channel members 2080 are interleaved by inner spacer features 216. In some embodiments, the inner spacer features 216 include silicon oxide, silicon nitride, silicon oxycarbide, silicon oxycarbonitride, silicon carbonitride, metal nitride, or a combination thereof. Depending on the dimensions and the shapes, the channel members 2080 may also be referred to as nanostructures, nanosheets, or nanowires. In the depicted embodiments, the lower channel member 2080L serves as a channel of a bottom multi-gate device and the upper channel member 2080U serves as a channel of a top multi-gate device. The middle channel members 2080M are vertically spaced apart by a middle dielectric layer 211 and, as described below, are disabled.

In some embodiments represented in FIG. 2, the active region may be divided into segments along the X direction by a plurality of dielectric features 209. In the depicted embodiments, each of the dielectric features 209 includes an outer layer 204 and an inner layer 206. In some implementations, a dielectric constant of the outer layer 204 is greater than a dielectric constant of the inner layer 206. The outer layer 206 is more etch resistant than the inner layer 204. In some embodiments, the out layer 204 includes a nitrogen-containing dielectric material, such as silicon nitride, silicon carbonitride, silicon oxynitride, or silicon oxycarbonitride. The inner layer 204 may include an oxygen-containing dielectric material, such as silicon oxide.

In some embodiments represented in FIG. 3, an active region may be spaced apart from an adjacent active region by a dielectric fin 215. As illustrated in FIG. 3, a dielectric fin 215 may extend at least partially into the isolation feature 207. In some embodiments, the dielectric fin 215 may include silicon nitride, silicon oxynitride, silicon carbonitride, or silicon oxycarbonitride.

The workpiece 200 also includes a lower gate structure 240P and an upper gate structure 240N. As shown in FIG. 2, the lower gate structure 240P wraps around the lower channel member 2080L and the upper gate structure 240N wraps around the upper channel member 2080U. Each of the lower gate structure 240P and the upper gate structure 240N includes an interfacial layer 212 to interface the channel members, a gate dielectric layer 213 over the interfacial layer 212, and at least one work function layer. In some embodiments, the interfacial layer 212 includes silicon oxide and may be formed on semiconductor surfaces (such as silicon surfaces) in a pre-clean process. An example pre-clean process may include use of RCA SC-1 (ammonia, hydrogen peroxide and water) and/or RCA SC-2 (hydrochloric acid, hydrogen peroxide and water). The gate dielectric layer 213 may be formed of high-K dielectric materials. As used and described herein, high-k dielectric materials include dielectric materials having a high dielectric constant, for example, greater than that of thermal silicon oxide (˜3.9). In one embodiment, the gate dielectric layer 213 includes hafnium oxide. Alternatively, the gate dielectric layer 213 may include other high-K dielectrics, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, or other suitable material. In some embodiments, the middle dielectric layer 211 is formed along with the inner spacer features 216 and shares the same composition with the inner spacer features 216. It is noted that neither the lower gate structure 240P and the upper gate structure 240N extends between the two middle channel members 2080M due to presence of the middle dielectric layer 211 and an isolation layer disposed between the lower gate structure 240P and the upper gate structure 240N. Sidewalls of the portion of the upper gate structure 240N above the upper channel members 2080U are lined by a gate spacer 214. The gate spacer 214 may be a single layer or a multilayer. In the embodiment depicted in FIG. 2, the gate spacer 214 may include a first spacer in contact with the upper gate structure 240N and a second spacer spaced apart from the upper gate structure 240N by the first spacer. In some instances, the gate spacer 214 includes silicon nitride, silicon oxycarbonitride, silicon oxynitride, or silicon carbonitride.

In the depicted embodiments, the lower gate structure 240P is a p-type gate structure and the upper gate structure 240N is an n-type gate structure. In these embodiments, the lower gate structure 240P and the upper gate structure 240N have different work function layer compositions. In some embodiments, the lower gate structure 240P includes at least one p-type work function layer and the upper gate structure 240N includes at least one n-type work function layer. Example p-type work function layer materials include titanium nitride (TiN), tantalum nitride (TaN), ruthenium (Ru), molybdenum (Mo), tungsten nitride (WN), zirconium silicide (ZrSi2), molybdenum silicide (MoSi2), tantalum silicide (TaSi2), nickel silicide (NiSi2), other p-type work function material, or combinations thereof. Example n-type work function layer materials include titanium (Ti), aluminum (Al), silver (Ag), manganese (Mn), zirconium (Zr), titanium aluminum (TiAl), titanium aluminum carbide (TiAlC), tantalum carbide (TaC), tantalum carbonitride (TaCN), tantalum silicide nitride (TaSiN), tantalum aluminum (TaAl), tantalum aluminum carbide (TaAlC), titanium aluminum nitride (TiAlN), other n-type work function material, or combinations thereof. In some embodiments, a metal gate cap layer may be deposited over the upper gate structure 240. The metal gate cap layer may include tungsten (W). In some alternative embodiments, the lower gate structure 240P and the upper gate structure 240N may share the same composition, with the exception of the metal gate cap layer, which is only found in the upper gate structure 240N.

The lower channel member 2080L extends between two p-type source/drain features 220P along the X direction. The upper channel member 2080U extends between two n-type source/drain features 220N along the X direction. Due to their relative locations, the p-type source/drain features 220P may be referred to as bottom source/drain features 220P and the n-type source/drain features 220N may be referred to as top source/drain features 220N. In some embodiments, the p-type source/drain features 220P include silicon germanium (SiGe) and a p-type dopant, such as boron (B) or boron difluoride (BF₂) and the n-type source/drain features 220N include silicon (Si) and an n-type dopant, such as phosphorus (P). The p-type source/drain features 220P and the n-type source/drain features 220N are deposited using epitaxial deposition methods, such as vapor-phase epitaxy (VPE), ultra-high vacuum chemical vapor deposition (UHV-CVD), molecular beam epitaxy (MBE). For that reasons, the p-type source/drain features 220P may be referred to as p-type epitaxial features and the n-type source/drain features 220N may be referred to as n-type epitaxial features. A p-type source/drain feature 220P and an n-type source/drain feature 220N disposed directly above are disposed between two adjacent dielectric fins 215.

In the depicted embodiments, the p-type source/drain features 220P are not deposited directly on the substrate 202 to reduce bulk leakage. Instead, the p-type source/drain features 220P are spaced apart from the substrate a leakage block layer (not shown). In some embodiments, the leakage block layer may include undoped semiconductor material, such as undoped silicon, undoped germanium, or undoped silicon germanium. In some other embodiments, the leakage block layer includes a dielectric material, such as silicon oxide or silicon nitride. When the leakage block layer is formed of semiconductor materials, it may be deposited using epitaxial deposition method, such as vapor-phase epitaxy (VPE), ultra-high vacuum chemical vapor deposition (UHV-CVD), molecular beam epitaxy (MBE). When the leakage block layer is formed of a dielectric material, it may be deposited using chemical vapor (CVD) deposition or a suitable deposition method.

As illustrated in FIG. 2, each of the p-type source/drain feature 220P and each of the n-type source/drain feature 220N may include more than one epitaxial layer. In some embodiments, the p-type source/drain feature 220P may include first epitaxial layer 221 in contact with sidewalls of the lower channel member 2080L and a second epitaxial layer 222 over the first epitaxial layer 221. The second epitaxial layer 222 may include a greater germanium content and a greater p-type dopant concentration than the first epitaxial layer 221 to reduce defects due to lattice mismatch. In some embodiments, the n-type source/drain feature 220N may include third epitaxial layer 223 in contact with sidewalls of the upper channel member 2080U and a fourth epitaxial layer 224 over the third epitaxial layer 223. The fourth epitaxial layer 224 may include a greater N-type dopant concentration than the third epitaxial layer 223 to reduce contact resistance.

Reference is still made to FIGS. 2 and 3. The workpiece 200 includes a lower contact etch stop layer (CESL) 232 and a lower interlayer dielectric (ILD) layer 234 over the p-type source/drain features 220P. The workpiece 200 also includes an upper CESL 236 over the n-type source/drain features 220N and an upper ILD layer 238 over the upper CESL 236. In some embodiments, the lower CESL 232 and the upper CESL 236 include silicon nitride or silicon oxynitride and the lower ILD layer 234 and the upper ILD layer 238 include silicon oxide. As shown in FIG. 3, the lower CESL 232 conformally covers a top surface of the isolation feature 207, sidewalls of the gate spacer 214 (or portions thereof) disposed along sidewalls of the fin structure 205, and exposed surfaces of the p-type source/drain features 220P. The lower ILD layer 234 fills the gap left behind by the lower CESL 232. The upper CESL 236 conformally covers a top surface of the lower ILD layer 234 and exposed surfaces of the n-type source/drain features 220N.

Reference is still made to FIGS. 2 and 3. Top surfaces of the gate spacer 214, the upper gate structure 240N, the upper CESL 236, and the upper ILD layer 238 are all coplanar, as a result a planarization process. The workpiece 200 further includes an etch stop layer (ESL) 242 on upper ILD layer 238, the upper CESL 236, the gate spacer 214, the dielectric features 209, and the upper gate structure 240N and an ILD layer 244 on the ESL 242. In some embodiments, the ESL 242 may include silicon nitride or silicon oxynitride and the ILD layer 244 may include silicon oxide.

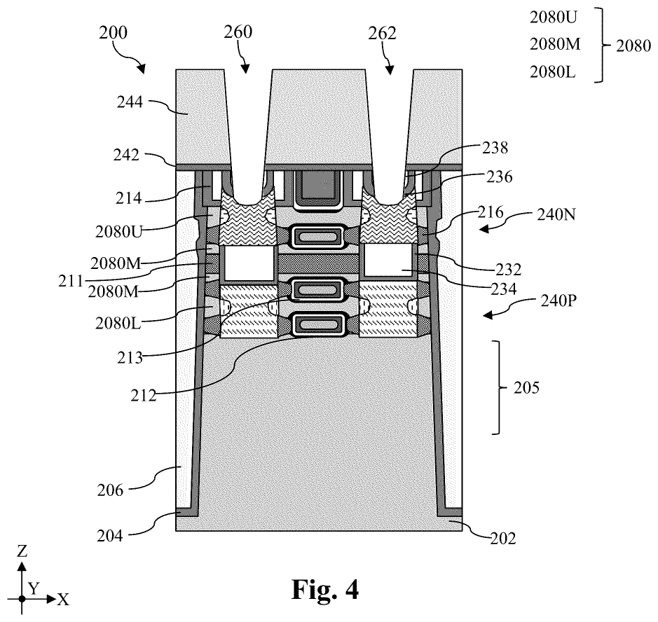

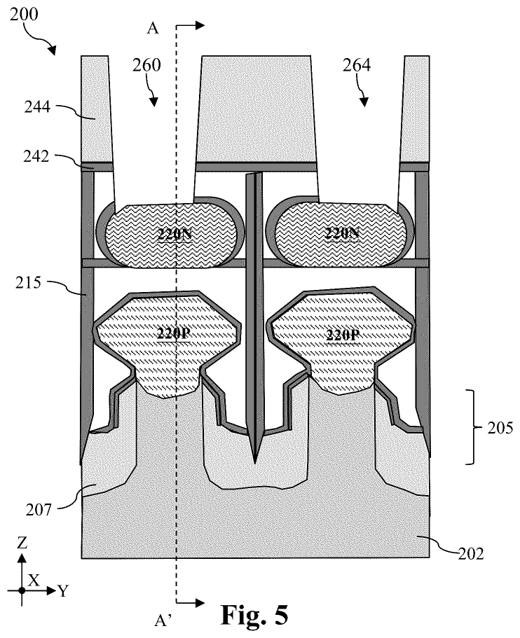

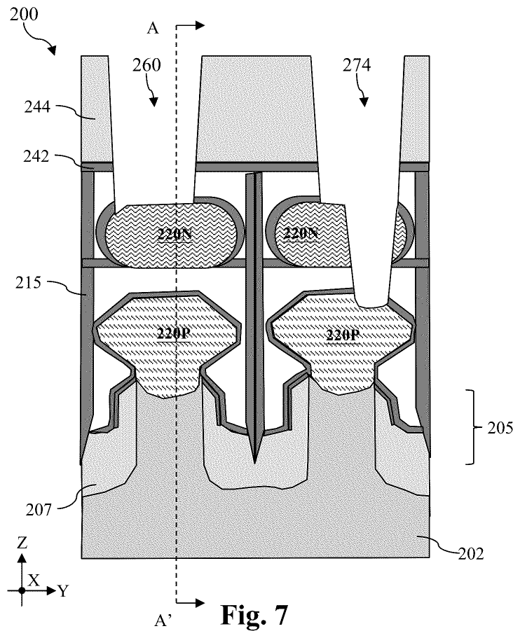

Referring to FIGS. 1 and 4-7, method 100 includes a block 104 where source/drain contact openings are formed. Operations at block 104 include formation of a patterned mask, formation of source/drain contact openings to expose the n-type source/drain features 220N, selective extension of at least one of the source/drain contact opening to reach a p-type source/drain feature 220P, and removal of the hard mask layers. It is noted that FIGS. 4, 6, and 8 illustrate cross-sectional views along the X direction while FIGS. 5 and 7 illustrate cross-sectional views along the Y direction. The p-type source/drain feature 220P and n-type source/drain feature 220N shown on the right hand side in FIGS. 4, 6, and 8, and 12 are different from their counterparts shown on the right hand side in FIGS. 5 and 7.

One or more hard mask layers are first deposited over the ILD layer 244. The one or more hard mask layers may tungsten carbide (WC), silicon oxide, amorphous silicon (a-Si), or silicon nitride. Each of the hard mask layers may be deposited using physical vapor deposition (PVD), CVD. ALD, or a suitable deposition method. Photolithography process may be used to pattern the one or more hard mask layers. In an example process, a photoresist layer is deposited over the workpiece 200, including the one or more hard mask layers. The photoresist layer is patterned using a photolithography process. The photolithography process may include soft baking, mask aligning, exposure, post-exposure baking, photoresist developing, rinsing, drying (e.g., spin-drying and/or hard baking), other suitable lithography techniques, and/or combinations thereof. The patterned photoresist layer is then applied as an etch mask to etch the underlying one or more hard mask layer to form the patterned hard mask. The etching process may include dry etching (e.g., RIE etching) or other etching methods.

Referring then to FIGS. 4 and 5, the patterned hard mask layer is applied as an etch mask to etch through ILD layer 244, ESL 242, the upper ILD layer 238, and the upper CESL 236 to form a first contact opening 260, a second contact opening 262, and a third contact opening 264. An anisotropic etch process may be used. For example, the anisotropic etch process may be a reactive-ion etching (RIE) process that includes use of a bromine-containing gas (e.g., HBr and/or CHBr₃), a fluorine-containing gas (e.g., CF₄, SF₆, NF₃, CH₂F₂, CHF₃, and/or C₂F₆), a carbon-containing gas (e.g., CH₄ or C₂H₆), other suitable gases, or combinations thereof. Each of the first contact opening 260, the second contact opening 262, and the third contact opening 264 exposes a portion of an n-type source/drain feature 220N.

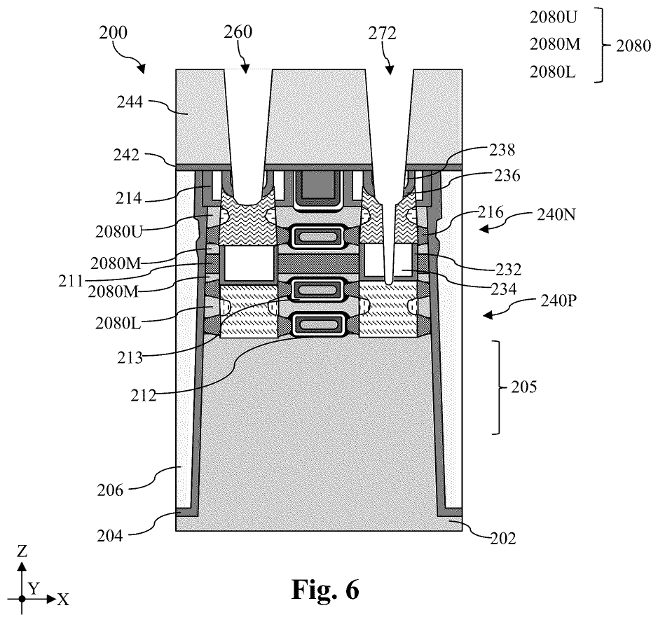

Reference is now made to FIGS. 6 and 7. The second contact opening 262 is partially extended further toward the substrate 202 to form a first extended opening 272. The third contact opening 264 is partially extended further toward the substrate 202 to form a second extended opening 274. Each of the first extended opening 272 and the second extended opening 274 exposes a p-type source/drain feature 220P and an overlying n-type source/drain feature 220N. To form the first extended opening 272 and the second extended opening 274. A bottom antireflective coating (BARC) layer may be deposited over the workpiece 200 to protect contact openings that are not to be extended further toward the substrate 202. After deposition of the BARC layer, photolithography process and etching process are then performed to form the first extended opening 272 and the second extended opening 274. Each of the first extended opening 272 and the second extended opening 274 extends through an n-type source/drain feature 220N, the lower ILD layer 234, and the lower CESL 232 to expose a p-type source/drain feature 220P.

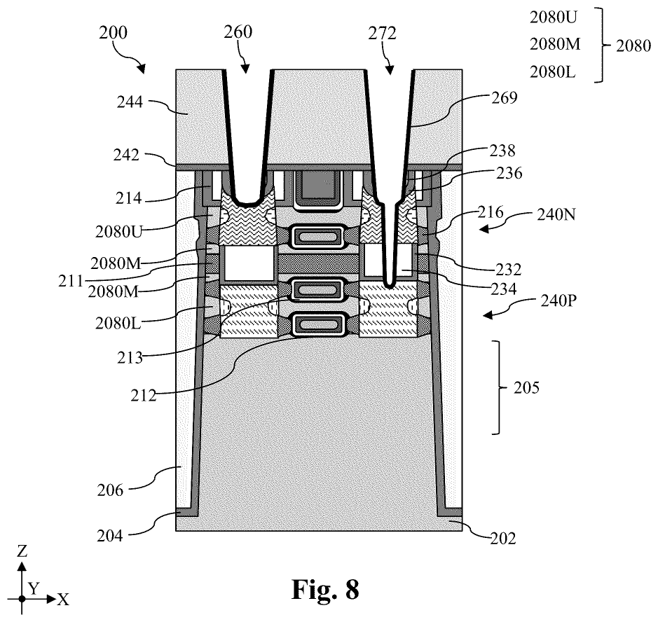

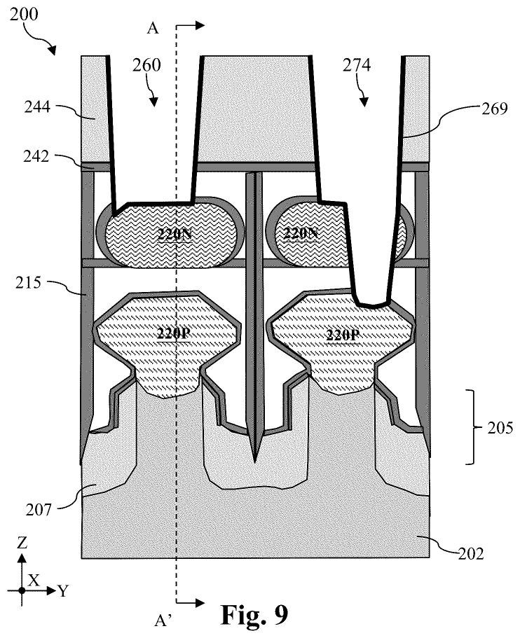

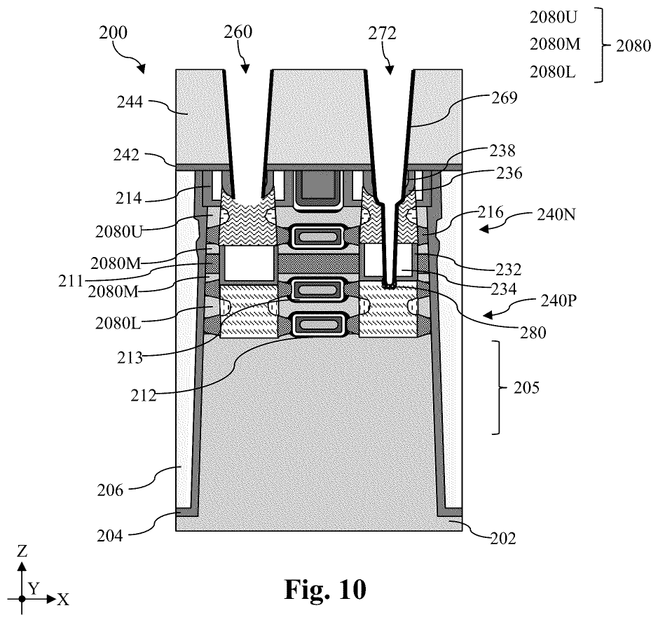

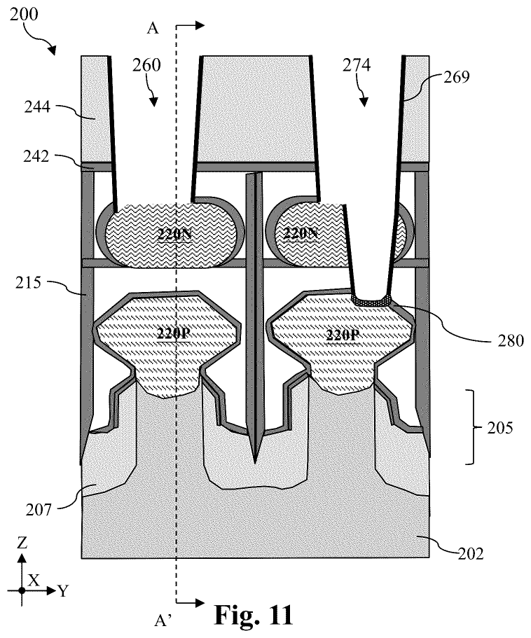

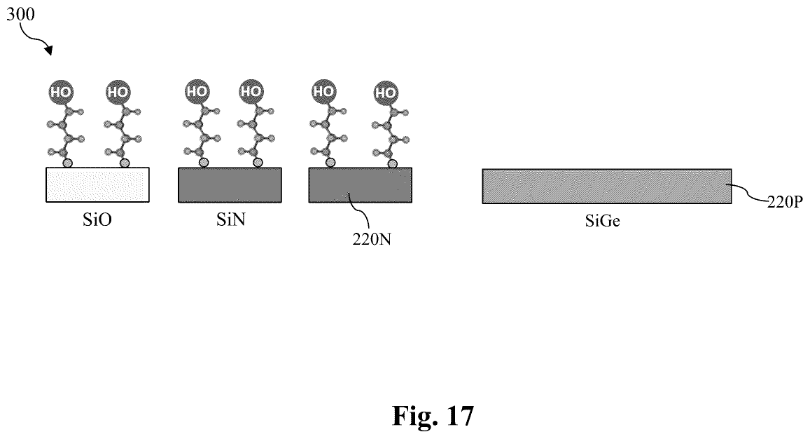

Referring to FIGS. 1 and 8-11, method 100 includes a block 106 where a first silicide layer 280 is selectively deposited on exposed p-type source/drain features 220P. Operations at block 106 may include conformal deposition of a sidewall liner 269, anisotropic etching to remove a portion of the sidewall liner 269 to expose the p-type source/drain feature 220P and the n-type source/drain feature 220N, and selective deposition of the first silicide layer 280. Referring to FIGS. 8 and 9, the sidewall liner 269 is conformally deposited over the first contact opening 260, the first extended opening 272, and the second extended opening 274 using chemical vapor deposition (CVD). In some instances, the sidewall liner 269 includes silicon nitride. Referring then to FIGS. 10 and 11, an anisotropic etch is performed to remove the sidewall liner 269 deposited on top-facing surfaces. The anisotropic etch exposes the n-type source/drain feature 220N in the first contact opening 260, the n-type source/drain feature 220N and the p-type source/drain feature 220P in the first extended opening 272, and the n-type source/drain feature 220N and the p-type source/drain feature 220P in the second extended opening 274. Referring still to FIGS. 10 and 11, the first silicide layer 280 is selectively deposited on exposed surfaces of the p-type source/drain features 220P but not substantially deposited on other surfaces that are formed of silicon or dielectric materials. By way of example, the present disclosure provides two mechanisms of the selective deposition of the first silicide layer 280 on the p-type source/drain features 220P. FIG. 16 illustrates a first mechanism where precursors of the first silicide layer 280 are more likely to react with silicon germanium surfaces (or germanium-containing surfaces) due to lower energy barrier. FIGS. 17-19 illustrate a second mechanism where a surface passivation layer 300 (or a surface block layer 300) is deposited on germanium-free surfaces, such as surfaces of silicon, silicon oxide, or silicon nitride before the first silicide layer 280 is deposited.

It is noted that the first mechanism and the second mechanism may be implemented individually or sequentially. In one embodiment, the first mechanism may be adopted to selectively deposit the first silicide layer on the p-type source/drain feature 220P. In some embodiments not explicitly shown, when the first mechanism is adopted, any unintentional deposition of the first silicide layer 280 on the n-type source/drain feature 220N may be removed by a cleaning or a selective etching process. In another embodiment, the second mechanism may be adopted to selectively deposit the first silicide layer on the p-type source/drain feature 220P by first forming the surface passivation layer 300 on germanium-free surfaces. In still another embodiment, both the first mechanism and the second mechanism may be adopted together. The surface passivation layer 300 is first formed on germanium-free surfaces and then the first silicide layer 280 is deposited on the p-type source/drain feature 220P.

Reference is first made to FIG. 16. FIG. 16 schematically illustrates surfaces that are exposed when the first silicide layer 280 is deposited. For example, the ILD layer 244 may include silicon oxide, the ESL 242 may include silicon nitride, the sidewall liner 269 may include silicon nitride, the lower ILD layer 234 may include silicon oxide, the lower CESL 232 may include silicon nitride, and the n-type source/drain features 220N include silicon. In the first mechanism shown in FIG. 16, the first silicide layer 280 is deposited using precursors that have a lower energy barrier to react with germanium on the p-type source/drain feature 220P. In some embodiments, the first silicide layer 280 includes tungsten (W), molybdenum (Mo), ruthenium (Ru), nickel (Ni), or cobalt (Co). In these embodiments, the precursor may include tungsten chloride (WCl₅), molybdenum chloride (MoCl₅), diazadiene nickel butadiene compounds (Ni(DAD)₂), diazadiene cobalt butadiene compounds (Co(DAD)₂), ruthenium (II) complexes (e.g., C₁₀H₁₄RuC₆H₁₀, C₁₆H₂₂O₆Ru, or Ru(C₅H₄C₂H₅)₂), or metal organic precursor that includes tungsten (W), molybdenum (Mo), ruthenium (Ru), nickel (Ni), or cobalt (Co). Among these examples, diazadiene nickel butadiene compounds (Ni(DAD)₂), diazadiene cobalt butadiene compounds (Co(DAD)₂), ruthenium (II) complexes (e.g., C₁₀H₁₄RuC₆H₁₀, C₁₆H₂₂O₆Ru, or Ru(C₅H₄C₂H₅)₂) may be considered metal organic precursors. In some embodiments, the precursor may be selectively deposited on the exposed surfaces of the p-type source/drain features 220P using ALD, plasma-enhanced ALD (PEALD), CVD, plasma-enhanced CVD (PECVD), or PVD. In one embodiment, the first silicide layer 280 is deposited using ALD or PEALD. In some instances, the deposition may take place at a temperature between about 250° C. and about 450° C., including about 350° C. and about 450° C., and at a pressure between about 10 mTorr to about 760 mTorr. In the foregoing temperature range, the metal precursors react with silicon and germanium in the p-type source/drain feature 220P to form the first silicide layer 280. In one embodiment where the precursor includes molybdenum, the first silicide layer 280 includes molybdenum silicide germanide (or molybdenum silicon germanide).

In the embodiments depicted in FIG. 16, a first silicide layer 280 may be deposited to have a thickness between about 3 nm and about 6.5 nm while no substantial growth of the first silicide layer 280 is observed on silicon oxide, silicon nitride, or silicon surfaces. This thickness range is not trivial. According to the present disclosure, the first silicide layer 280 also serves as a diffusion block layer to block diffusion of the n-type dipole layer 282 (to be described in detail below) into the p-type source/drain feature 220P. Because the interdiffusion of metal at the process temperatures described herein is likely to result in a diffusion depth of about 2 nm, when the first silicide layer 280 is thinner than 3 nm, metal in the n-type dipole layer 282 is likely to diffusion into the p-type source/drain feature 220P. When that happens, the contact resistance to the p-type source/drain feature 220P will increase, compromising the entire efforts to selectively deposit the first silicide layer 280 in the first place. When the first silicide layer 280 is thicker than 6.5 nm, too much first silicide layer 280 may be deposited, albeit unintentionally, on the n-type source/drain feature 220N, which will increase the contact resistance to the n-type source/drain feature. When the first mechanism is adopted, impurity in the precursor may remain in the first silicide layer 280. Example impurity compositions may include chlorine (Cl), carbon (C), nitrogen (N), or fluorine (F).

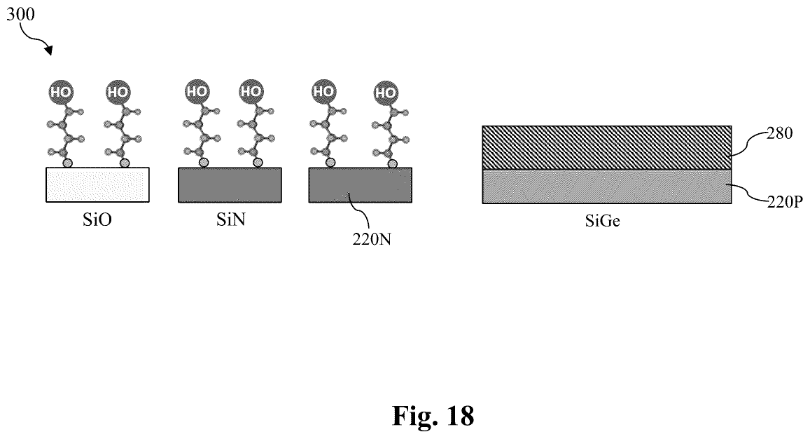

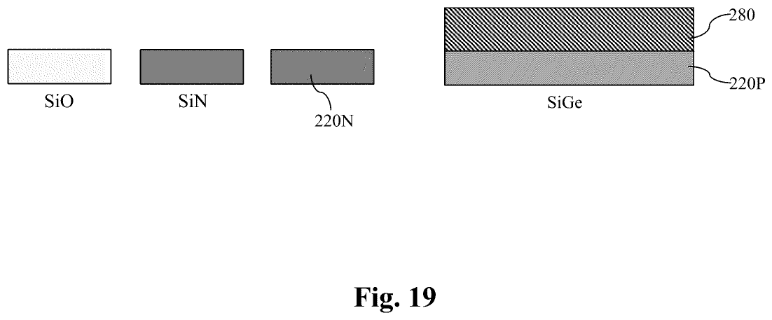

Reference is now made to FIGS. 17-19. Similar to FIG. 16, FIG. 17 schematically illustrates surfaces that are exposed when the first silicide layer 280 is deposited, which includes silicon oxide surfaces, silicon nitride surfaces, silicon surfaces (n-type source/drain features 220N), and silicon germanium surfaces (p-type source/drain features 220P). Different from the first mechanism, a self-assembled monolayer (SAM) layer is selectively formed on germanium-free surfaces, such as silicon oxide surfaces, silicon nitride surfaces, silicon surfaces to form a surface passivation layer 300. The SAM layer may include a polymer chain and a functional group that is reactive with dangling hydroxyl bonds on germanium-free surfaces but is unlikely to react with germanium or germanium oxide surface. Germanium is prone to oxidation and that is why germanium oxide is often present on germanium surfaces. For example, the SAM layer may include dithiothreitol, 3-(trimethoxysilyl) propanethiol, or other thiol-containing functional groups. The surface passivation layer 300 formed from the SAM layer may act as an inhibitor to precursors of the first silicide layer 280. Once the surface passivation layer 300 is formed on silicon oxide surfaces, silicon nitride surfaces, and silicon surfaces, the first silicide layer 280 may be deposited using the precursor described above or an ALD deposition process that includes use of a metal-containing precursor (e.g., molybdenum chloride (MoCl₅)), silicon-containing precursor (e.g., silane (SiH₄), disilane (Si₂H₆), or dichlorosilane (SiCl₂H₂), and/or a germanium containing precursor (e.g., germane (GeH₄)). Due to the formation of the surface passivation layer 300, the first silicide layer 280 may be selectively formed on exposed surfaces of the p-type source/drain features 220P, as representatively shown in FIG. 18. After the deposition of the first silicide layer 280, the surface passivation layer 300 may be removed by ashing, as shown in FIG. 19. An example ashing process includes treatment with plasma of argon (Ar), helium (He), nitrogen (N₂), or hydrogen (H₂).

Referring to FIGS. 1, 12 and 13, method 100 includes a block 108 where an n-type dipole layer 282 is globally deposited over the workpiece 200. In some embodiments, the n-type dipole layer 282 includes zirconium (Zr), hafnium (Hf), antimony (Sb), cerium (Ce), scandium (Sc), yittrium (Y), ytterbium (Yb), erbium (Er), or lanthanum (La). The n-type dipole layer 282 may be deposited using ALD or PEALD at a temperature between about 50° C. and about 450° C. and at a pressure between 10 mTorr and about 760 mTorr. Precursors used to deposit the n-type dipole layer 282 may include zirconium chloride (ZrCl), hafnium chloride (HfCl), antimony chloride (SbCl), tris(dimethylamino) antimony, tris(ethylsilyl) antimony, tris(trimethylsilyl) antimony, or an organic precursor of cerium (Ce), scandium (Sc), yittrium (Y), ytterbium (Yb), erbium (Er), or lanthanum (La). In some implementations, the n-type dipole layer 282 may be formed to a thickness between 0.5 and 1.5 nm to fully cover surfaces of the contact openings, exposed surfaces of the n-type source/drain features 220N, and the first silicide layer 280. The precursors described above may introduce impurities into the n-type dipole layer 282. For example, the n-type dipole layer 282 may include chlorine (Cl), carbon (C), oxygen (O), nitrogen (N), or fluorine (F).

Referring to FIGS. 1, 14 and 15, method 100 includes a block 110 where a second silicide layer 284 is globally deposited over the workpiece 200. The second silicide layer 284 has a metal composition different from that of the first silicide layer 280 or the n-type dipole layer 282. Put differently, the second silicide layer 284 is formed of a metal that is not found in the first silicide layer 280 or the n-type dipole layer 282. In some embodiments, the second silicide layer 284 includes titanium (Ti) and is deposited using ALD, PEALD, CVD, PECVD, or a suitable deposition method. Precursors used to deposit the second silicide layer 284 may include a titanium containing precursor (e.g., titanium tetrachloride) and a silicon containing precursor (e.g., silane (SiH₄), disilane (Si₂H₆), or dichlorosilane (SiCl₂H₂)). The second silicide layer 284 may be deposited at a temperature between about 250° C. and about 450° C., including about 350° C. and about 450° C., and at a pressure between 10 mTorr and about 760 mTorr.

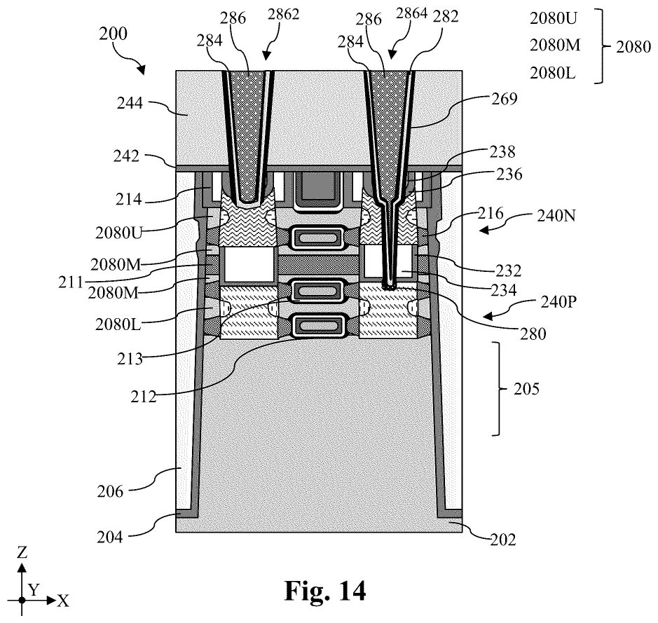

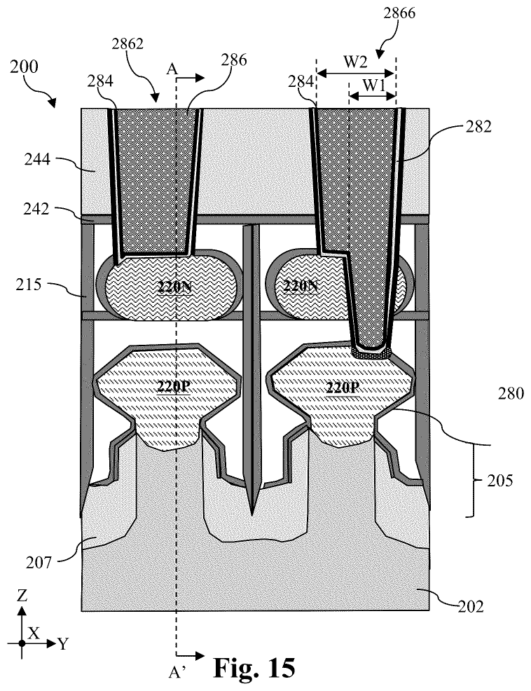

Referring to FIGS. 1, 14 and 15, method 100 includes a block 112 where a metal fill layer 286 is deposited over the workpiece 200. In some embodiments, the metal fill layer 286 may include tungsten (W), molybdenum (Mo), ruthenium (Ru), nickel (Ni), or cobalt (Co). In one embodiment, the metal fill layer 286 includes cobalt (Co). The metal fill layer 286 may be deposited using ALD, PVD, CVD, electroplating, or electroless plating. After the deposition of the metal fill layer 286, the workpiece 200 is planarized to remove excess materials. The planarization may include use of a chemical mechanical polishing (CMP) process. As shown in FIGS. 14 and 15, after the planarization, a first source/drain contact 2862, a second source/drain contact 2864, and a third source/drain contact 2866 are formed.

When viewed along the Y direction, as shown in FIG. 14, the first source/drain contact 2862, the second source/drain contact 2864, and the third source/drain contact 2866 (not shown in FIG. 14) have substantially the same width along the X direction. When viewed along the X direction, as shown in FIG. 15, the first source/drain contact 2862 and the third source/drain contact 2866 can be divided into a bottom portion and a top portion over the bottom portion. Referring to FIG. 15, the bottom portion of the third source/drain contact 2866 has a first width W1 along the Y direction and the top portion of the third source/drain contact 2866 has a second width W2 along the Y direction. The second width W2 is greater than the first width W1 such that the third source/drain contact 2866 does not substantially damage the n-type source/drain feature 220N it penetrates. A ratio of the second width W2 to the first width W1 may be between about 1.5 and about 3. As shown in FIG. 15, when the bottom portion of the third source/drain contact 2866 shares the same width with the top portion, it may wipe out a substantial portion of the n-type source/drain feature 220N. A bottom surface of the top portion of the third source/drain contact 2866 interfaces a top surface of the n-type source/drain feature 220N by way of the second silicide layer 284 and the n-type dipole layer 282. A terminal end of the bottom portion of the third source/drain contact 2866 interfaces the p-type source/drain feature 220P by way of the second silicide layer 284, the n-type dipole layer 282, and the first silicide layer 280. While not explicitly shown in the figures, the second source/drain contact 2864 may have a X-direction profile similar to that of the third source/drain contact 2866 shown in FIG. 15.

Reference is still made to FIGS. 14 and 15. The first source/drain contact 2862, the second source/drain contact 2864, and the third source/drain contact 2866 interfaces n-type source/drain features 220N by way of the n-type dipole layer 282. The second source/drain contact 2864, and the third source/drain contact 2866 interfaces p-type source/drain features 220P by way of the first silicide layer 280. The n-type dipole layer 282 reduces contact resistance to n-type source/drain features 220N and the first silicide layer 280 reduces contact resistance to p-type source/drain features 220P. It can be seen that the selective deposition of the first silicide layer 280 on p-type source/drain features 220P according to the present disclosure allows optimization of contact resistance reduction to both n-type source/drain features 220N and p-type source/drain features 220P. The interfaces of these layers may be observed using transmission electron microscope (TEM) or energy-dispersive X-ray spectroscopy (EDS).

In one exemplary aspect, the present disclosure is directed to a semiconductor structure. The semiconductor structure includes a fin structure arising from a substrate, an isolation feature surrounding the fin structure, a first type epitaxial feature disposed over the fin structure, a first contact etching stop layer (CESL) disposed on the first type epitaxial feature and the isolation feature, a first dielectric layer disposed over the first CESL, a second type epitaxial feature disposed on the first dielectric layer, a second CESL disposed on the first dielectric layer and the second type epitaxial feature, a second dielectric layer disposed over the second CESL, and a contact structure that includes a top portion extending through the second dielectric layer and the second CESL and contacting the second type epitaxial feature by way of a first metal silicide layer and a dipole layer, and a bottom portion disposed below the top portion, the bottom portion extending through the second type epitaxial feature, the first dielectric layer, and the first CESL and contacting the first type epitaxial feature by way of the first metal silicide layer, the dipole layer and a second metal silicide layer. The first metal silicide layer and the second metal silicide layer have different metal compositions.

In some embodiments, the first metal silicide layer includes Ti. In some implementations, the second metal silicide layer includes Mo, Ru, Ni, or Co. In some embodiments, the dipole layer includes Zr, Hf, Sb, Ce, Sc, Y, Yb, or Er. In some instances, the fin structure extends lengthwise along a first direction, the top portion of the contact structure includes a first width along a second direction perpendicular to the first direction, the bottom portion of the contact structure includes a second width along the second direction, and the first width is greater than the second width. In some embodiments, the second metal silicide layer includes a thickness between about 3 nm and about 6.5 nm. In some embodiments, sidewalls of the contact structure are spaced apart from the first CESL, the first dielectric layer, the second type epitaxial feature, the second CESL, and the second dielectric layer by a dielectric liner. In some instances, the dielectric liner includes silicon nitride. In some implementations, the first type epitaxial feature and the second type epitaxial feature are disposed between two dielectric fins.

In another exemplary aspect, the present disclosure is directed to a semiconductor structure. The semiconductor structure includes a first plurality of nanostructures extending between a first p-type source/drain feature and a second p-type source/drain feature, a second plurality of nanostructures disposed over the first plurality of nanostructures, the second plurality of nanostructures extending between a first n-type source/drain feature and a second n-type source/drain feature, a first contact contacting a top surface of the first n-type source/drain feature by way of a first metal silicide layer and an n-type dipole layer, and a second contact contacting a top surface of the second p-type source/drain feature by way of the first metal silicide layer, the n-type dipole layer and a second metal silicide layer. The first metal silicide layer and the second metal silicide layer have different metal compositions.

In some embodiments, the first metal silicide layer includes Ti. In some implementations, the second metal silicide layer includes Mo, Ru, Ni, or Co. In some embodiments, the n-type dipole layer includes Zr, Hf, Sb, Ce, Sc, Y, Yb, or Er. In some embodiments, the first contact and the second contact includes Mo, Ru, Ni, or Co. In some implementations, the second metal silicide layer includes chlorine, carbon, oxygen, nitrogen, or fluorine.

In yet another exemplary aspect, the present disclosure is directed to a method. The method includes receiving a workpiece including an opening that exposes a surface of an n-type source/drain feature and a surface of a p-type source/drain feature, selectively depositing a first silicide layer on the surface of the p-type source/drain feature while the surface of the n-type source/drain feature is substantially free of the first silicide layer, after the selectively depositing, depositing a metal layer on the first silicide layer and the surface of the n-type source/drain feature, depositing a second silicide layer over the metal layer, and depositing a metal fill layer over the second silicide layer. The the selectively depositing includes passivating the surface of the surface of the n-type source/drain features with a self-assembly layer, after the passivating, depositing the first silicide layer on the surface of the p-type source/drain feature, and after the selectively depositing of the first silicide layer, removing the self-assembly layer.

In some embodiments, the self-assembly layer includes dithiothreitol or 3-(trimethoxysilyl) propanethiol. In some implementations, the selectively depositing of the first silicide layer includes a temperature between about 250° C. and about 400° C. In some embodiments, the removing of the self-assembly layer includes a treatment with a plasma including argon, helium, nitrogen, or hydrogen. In some implementations, the first silicide layer includes Mo, Ru, Ni, or Co.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a fin structure arising from a substrate;
an isolation feature surrounding the fin structure;
a first type epitaxial feature disposed over the fin structure;
a first contact etching stop layer (CESL) disposed on the first type epitaxial feature and the isolation feature;
a first dielectric layer disposed over the first CESL;
a second type epitaxial feature disposed on the first dielectric layer;
a second CESL disposed on the first dielectric layer and the second type epitaxial feature;
a second dielectric layer disposed over the second CESL; and
a contact structure comprising:
a top portion extending through the second dielectric layer and the second CESL and contacting the second type epitaxial feature by way of a first metal silicide layer and a dipole layer, and
a bottom portion disposed below the top portion, the bottom portion extending through the second type epitaxial feature, the first dielectric layer, and the first CESL and contacting the first type epitaxial feature by way of the first metal silicide layer, the dipole layer and a second metal silicide layer,
wherein the first metal silicide layer and the second metal silicide layer have different metal compositions.

2. The semiconductor structure of claim 1, wherein the first metal silicide layer comprises Ti.

3. The semiconductor structure of claim 2, wherein the second metal silicide layer comprises Mo, Ru, Ni, or Co.

4. The semiconductor structure of claim 3, wherein the dipole layer comprises Zr, Hf, Sb, Ce, Sc, Y, Yb, or Er.

5. The semiconductor structure of claim 1,
wherein the fin structure extends lengthwise along a first direction,
wherein the top portion of the contact structure comprises a first width along a second direction perpendicular to the first direction,
wherein the bottom portion of the contact structure comprises a second width along the second direction,
wherein the first width is greater than the second width.

6. The semiconductor structure of claim 1, wherein the second metal silicide layer comprises a thickness between about 3 nm and about 6.5 nm.

7. The semiconductor structure of claim 1, wherein sidewalls of the contact structure are spaced apart from the first CESL, the first dielectric layer, the second type epitaxial feature, the second CESL, and the second dielectric layer by a dielectric liner.

8. The semiconductor structure of claim 7, wherein the dielectric liner comprises silicon nitride.

9. The semiconductor structure of claim 1, wherein the first type epitaxial feature and the second type epitaxial feature are disposed between two dielectric fins.

10. A semiconductor structure, comprising:
a first plurality of nanostructures extending between a first p-type source/drain feature and a second p-type source/drain feature;
a second plurality of nanostructures disposed over the first plurality of nanostructures, the second plurality of nanostructures extending between a first n-type source/drain feature and a second n-type source/drain feature;
a first contact contacting a top surface of the first n-type source/drain feature by way of a first metal silicide layer and an n-type dipole layer; and
a second contact contacting a top surface of the second p-type source/drain feature by way of the first metal silicide layer, the n-type dipole layer and a second metal silicide layer,
wherein the first metal silicide layer and the second metal silicide layer have different metal compositions.

11. The semiconductor structure of claim 10, wherein the first metal silicide layer comprises Ti.

12. The semiconductor structure of claim 11, wherein the second metal silicide layer comprises Mo, Ru, Ni, or Co.

13. The semiconductor structure of claim 12, where the n-type dipole layer comprises Zr, Hf, Sb, Ce, Sc, Y, Yb, or Er.

14. The semiconductor structure of claim 10, wherein the first contact and the second contact comprise Mo, Ru, Ni, or Co.

15. The semiconductor structure of claim 10, wherein the second metal silicide layer comprises chlorine, carbon, oxygen, nitrogen, or fluorine.

16. A method, comprising:
receiving a workpiece comprising an opening that exposes a surface of an n-type source/drain feature and a surface of a p-type source/drain feature;
selectively depositing a first silicide layer on the surface of the p-type source/drain feature while the surface of the n-type source/drain feature is substantially free of the first silicide layer;
after the selectively depositing, depositing a metal layer on the first silicide layer and the surface of the n-type source/drain feature;
depositing a second silicide layer over the metal layer; and
depositing a metal fill layer over the second silicide layer,
wherein the selectively depositing comprises:
passivating the surface of the surface of the n-type source/drain features with a self-assembly layer,
after the passivating, depositing the first silicide layer on the surface of the p-type source/drain feature, and
after the selectively depositing of the first silicide layer, removing the self-assembly layer.

17. The method of claim 16, wherein the self-assembly layer comprises dithiothreitol or 3-(trimethoxysilyl) propanethiol.

18. The method of claim 16, wherein the selectively depositing of the first silicide layer comprises a temperature between about 250° C. and about 400° C.

19. The method of claim 16, wherein the removing of the self-assembly layer comprises a treatment with a plasma comprising argon, helium, nitrogen, or hydrogen.

20. The method of claim 16, wherein the first silicide layer comprises Mo, Ru, Ni, or Co.
